(19) United States
(12) Patent Application Publication
(10) Pub. No.: US 2020/0134281 A1
(43) Pub. Date: Apr. 30, 2020

(54) DISPLAY PANEL, DISPLAY DEVICE, AND METHOD FOR DRIVING THE SAME

(71) Applicant: BOE Technology Group Co., Ltd., Beijing (CN)

(72) Inventors: Yanling HAN, Beijing (CN); Yuzhen GUO, Beijing (CN); Yunke QIN, Beijing (CN); Yanan JIA, Beijing (CN); Lijun ZHAO, Beijing (CN)

(21) Appl. No.: 15/778,485

(22) PCT Filed: Oct. 19, 2017
(86) PCT No.: PCT/CN2017/106862

§ 371 Date: May 23, 2018

(30) Foreign Application Priority Data
Mar. 28, 2017 (CN) 201710193999.X

(51) Int. Cl. G06K 9/00; G06F 3/01; H01L 27/32; G02F 1/1362

(52) U.S. Cl. CPC G06K 9/0004; G06F 3/017; H01L 27/3276; G02F 2001/136222; H01L 27/3246; G02F 1/136209; H01L 27/3218

(57) ABSTRACT

The disclosure discloses a display panel, a display device, and a method for driving the same, where switch transistors connected with scan signal lines are controlled by the scan signal lines to be switched on or off, and when the switch transistors are switched on, the bias voltage higher than the avalanche voltage is applied to the photosensitive diodes over the drive signal lines. While a fingerprint is being recognized, the photosensitive diodes are broken through reversely due to infrared light reflected by ridges, so that large current is produced, and output to read signal lines through sample resistors; and the photosensitive diodes corresponding valleys output zero current.

This application is a National Stage of International Application No. PCT/CN2017/106862, filed Oct. 19, 2017, which claims the benefit of Chinese Patent Application No. 201710193999.X, filed with the Chinese Patent Office on Mar. 28, 2017, and entitled “A display panel, a display device, and a method for driving the same”, both of which are hereby incorporated by reference in their entireties.

### FIELD

The present disclosure relates to the field of display technologies, and particularly to a display panel, a display device, and a method for driving the same.

### BACKGROUND

There are capacitive, ultrasonic, etc., fingerprint recognition elements currently integrated in a display panel, and they have their respective advantages and disadvantages, but they have such a common drawback of a short sense distance of a sensor that seriously restricts the structure and performance of the fingerprint recognition elements, and thus discourages them from being widely applied to mobile terminal products.

### SUMMARY

An embodiment of this disclosure provides a display panel includes: a plurality of photosensitive sensing circuits arranged in an array, a plurality of scan signal lines corresponding to each row of the plurality of photosensitive sensing circuits, and a plurality of read signal lines, and a plurality of drive signal lines, both of which correspond to each column of the plurality of photosensitive sensing circuits; and each of the photosensitive sensing circuits includes a photosensitive diode, a switch transistor and a sample resistor, where the switch transistor includes a gate connected with a corresponding scan signal line, a source connected with a cathode of the photosensitive diode, and a drain connected with a corresponding drive signal line; the photosensitive diode includes an anode connected with a first end of the sample resistor, and a second end of the sample resistor is grounded; and the first end of the sample resistor is connected with a corresponding read signal line.

In the display panel above according to the embodiment of this disclosure, the display panel further includes at least one infrared light-emitting source, and the photosensitive diode is an infrared photosensitive diode; and a projection of the infrared light-emitting source in a direction perpendicular to the display panel does not overlap with projections of the photosensitive sensing circuits in the direction.

In the display panel above according to the embodiment of this disclosure, the display panel is divided into a display area, and a bezel area surrounding the display area, and the photosensitive sensing circuits are located in the display area; and the display area further includes: a plurality of pixel elements arranged in an array, at least a part of the plurality of pixel elements include at least four sub-pixel areas, where one infrared light-emitting source is arranged in one of the sub-pixel areas, and sub-pixel structures for displaying are arranged in a rest of the sub-pixel areas.

In the display panel above according to the embodiment of this disclosure, projections of the photosensitive sensing circuits in a direction perpendicular to the display panel lie at gaps between the sub-pixel areas.

In the display panel above according to the embodiment of this disclosure, the sub-pixel structures are organic light-emitting diodes located on an underlying substrate, and a protective cover is arranged on a side of the organic light-emitting diodes away from the underlying substrate; and the photosensitive sensing circuits are located on the surface of the protective cover facing the organic light-emitting diodes.

In the display panel above according to the embodiment of this disclosure, the sub-pixel structures are organic light-emitting diodes located on an underlying substrate, and pixel definition layers are arranged between each of the sub-pixel areas; and the photosensitive sensing circuits are located between the pixel definition layers and the underlying substrate.

In the display panel above according to the embodiment of this disclosure, the display panel is a liquid crystal display panel, and includes an opposite substrate and an array substrate; the opposite substrate and an array substrate are arranged opposite to each other; and a black matrix is arranged on a side of the opposite substrate facing the array substrate; and the photosensitive sensing circuits are located on a surface of the black matrix away from the opposite substrate.

In the display panel above according to the embodiment of this disclosure, the display panel is a liquid crystal display panel, and includes an opposite substrate and an array substrate, the opposite substrate and an array substrate are arranged opposite to each other; and the photosensitive sensing circuits are arranged on a side of the array substrate facing the opposite substrate.

In the display panel above according to the embodiment of this disclosure, color filter sheets are arranged on a side of the opposite array substrate facing the array substrate; and the infrared light-emitting source includes an infrared electroluminescent layer; the infrared electroluminescent layer and the color filter sheets are located at a same layer.

In the display panel above according to the embodiment of this disclosure, the display panel includes a display area, and a bezel area surrounding the display area; and the infrared light-emitting source is located in the bezel area.

An embodiment of this disclosure further provides a display device including the display panel above according to the embodiment of this disclosure.

In the display device above according to the embodiment of this disclosure, the display device further includes a front camera.

An embodiment of this disclosure further provides a method for driving the display device above, the method includes: applying bias voltage to each of driver signal lines at least in a target detection area, wherein the bias voltage is higher than an avalanche voltage of the photosensitive diodes; and scanning each of scan signal lines at least in the target detection area sequentially in rows, and obtaining at least output signals of each of read signal lines in the target detection area.

In the driving method above according to the embodiment of this disclosure, the bias voltage is applied to all of the driver signal lines; and the scan signal lines are scanned sequentially in rows, and the output signals of the read signal lines are obtained.

In the driving method above according to the embodiment of this disclosure, while a floating touch is being detected, the method further includes: taking a photo of a gesture using a front camera, and determining positional coordinates of a gesture in a plane.

In the driving method above according to the embodiment of this disclosure, the method further includes: determining the target detection area according to determined positional coordinates of the gesture in the plane.

### BRIEF DESCRIPTION OF THE DRAWINGS

FIG. 1 is a schematic structural diagram of a fingerprint detection structure in the related art.

FIG. 2 is a schematic circuit diagram of a display panel according to an embodiment of this disclosure.

FIG. 3 is a signal timing diagram corresponding to FIG. 2.

FIG. 4 is a schematic structural diagram of the display panel according to an embodiment of this disclosure in a top view.

FIG. 5 to FIG. 8 are schematic structural diagrams respectively of the display panel according to an embodiment of this disclosure in side views.

### DETAILED DESCRIPTION OF THE EMBODIMENTS

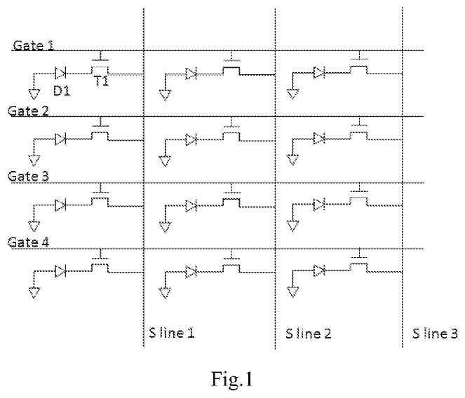

FIG. 1 illustrates a fingerprint detection structure based upon on a photo sensor in the related art, where each fingerprint detection unit includes a photosensitive diode D1 and a switch transistor T1. While a fingerprint is being scanned, light from a light source incident on a finger may be reflected differently due to differences between valleys and ridges of the finger, so that the strengths of the light arriving at the photosensitive diodes D1 vary, thus resulting in varying difference ins light current, and the differences in current of the respective photosensitive diodes D1 are read out in sequence under the control of the switch transistors T1 connected with the photosensitive diodes D1 to thereby detect the valleys and the ridges of the finger.

However a drawback of this design lies in that the differences in current arising from the valleys and ridges are so small that there is such low current flowing through read lines Sline that tends to be affected by charging and discharging of other stray capacitors, and leakage current in switches of scan lines Gate of other rows, thus resulting in considerable noise; and the current is so low that a magnification factor of a detection chip (IC) front end is required to be large, thus necessitating a precise and large resistor. Bias current in a front end amplifier is required to be low because some signal current may be consumed by large bias current, and even the current may not be detected due to the large bias current. Both of the two considerations may greatly increase a cost of fabricating the IC, and the volume of the IC, thus degrading a possible production throughput.

In view of the problem in the related art of the difficulty to detect a weak current signal in the photo sensor, embodiments of the disclosure provide a display panel, a display device, and a method for driving the same. In order to make the objects, technical solutions, and advantages of the disclosure more apparent, optional implementations of the display panel, the display device, and the method for driving the same according to the embodiments of the disclosure will be described below in details with reference to the drawings. It shall be appreciated that the preferable embodiments to be described below are merely intended to illustrate and explain the disclosure, but not to limit the disclosure thereto, and the embodiments of the disclosure, and the features in the embodiments can be combined with each other unless they conflict with each other.

The shapes and sizes of respective components in the drawings are not intended to reflect any real proportion, but only intended to illustrate the disclosure of the disclosure.

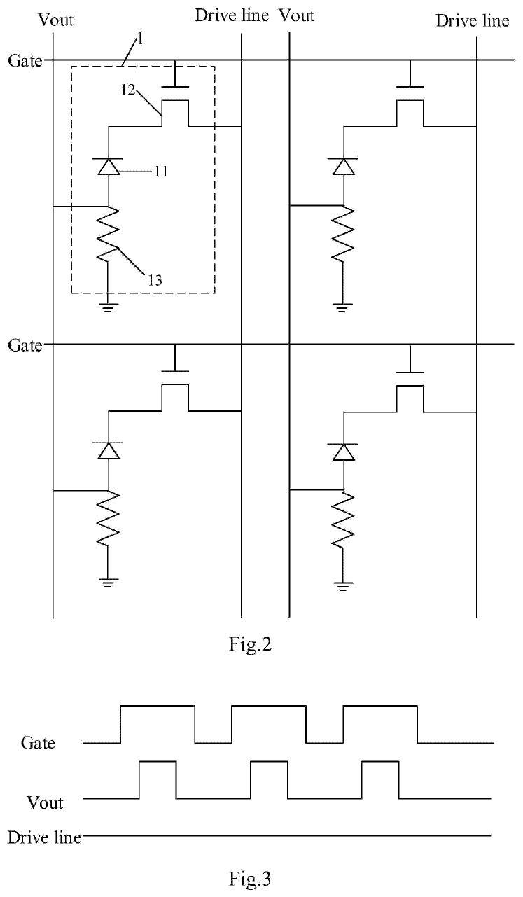

Optionally an embodiment of this disclosure provides a display panel as illustrated in FIG. 2, which includes: a plurality of photosensitive sensing circuits 1 arranged in an array, a plurality of scan signal lines Gate corresponding to respective rows of photosensitive sensing circuits 1, and a plurality of read signal lines Vout, and a plurality of drive signal lines Drive Line, both of which correspond to respective columns of photosensitive sensing circuits 2; and the respective photosensitive sensing circuits 1 include a photosensitive diode 11, a switch transistor 12, and a sample resistor 13.

The switch transistor 12 includes a gate connected with corresponding scan signal lines Gate, a source connected with a cathode of the photosensitive diode 11, and a drain connected with a corresponding drive signal line Drive Line.

The photosensitive diode 11 includes an anode connected with a first end of the sample resistor 13, and a second end of the sample resistor 13 is grounded.

The first end of the sample resistor 13 is connected with a corresponding read signal line Vout.

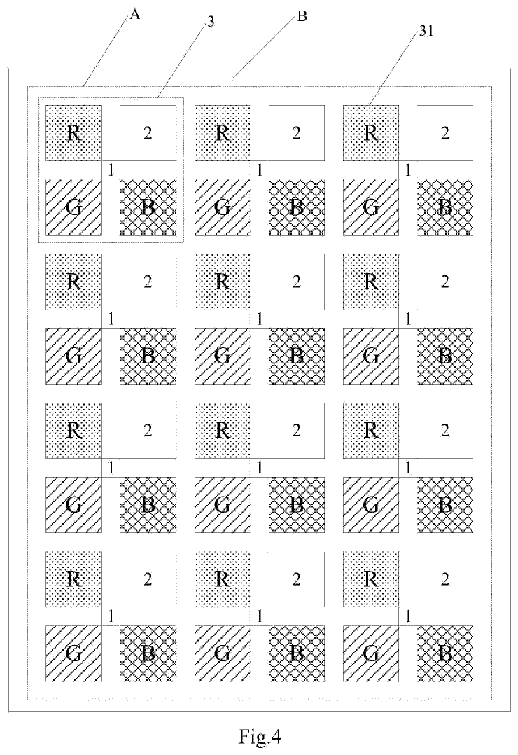

Optionally in the display panel above according to the embodiment of this disclosure, referring to the timing diagram illustrated in FIG. 3, the switch transistor 12 connected with the scan signal lines Gate is controlled by the scan signal line to be switched on or off, and when the switch transistor 12 is switched on, bias voltage higher than avalanche voltage is applied to the photosensitive diode 11 over the drive signal line Drive Line. While a fingerprint is being recognized, the photosensitive diode 11 is broken through reversely due to infrared light reflected by ridges, so that large current is produced and output to the read signal lines Vout through the sample resistor 13; and the photosensitive diode 11 corresponding valleys outputs zero current. In this way, the valleys and the ridges are distinguished from each other. The photosensitive diode 11 being illuminated is broken through reversely so that the large current is produced, so there is a significant difference in detection signal between the valleys and the ridges while a fingerprint is being recognized in the embodiment of this disclosure, thus lowering the difficulty of detection in an IC detection circuit, and improving the precision of detection in fingerprint recognition.

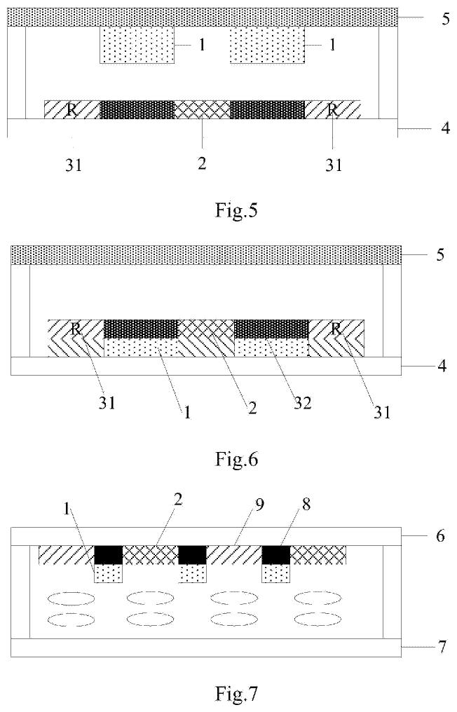

Optionally in the display panel above according to an embodiment of this disclosure, as illustrated in FIG. 4 to FIG. 7, the display panel can further include at least one infrared light-emitting source 2, where the photosensitive diode 11 is an infrared photosensitive diode.

A projection of the infrared light-emitting source 2 in a direction perpendicular to the display panel does not overlap with a projection of the photosensitive sensing circuit 1 in the direction.

Optionally in the display panel above according to an embodiment of this disclosure, when the infrared light-emitting source 2 is arranged, the photosensitive sensing circuit 1 can further perform a function of recognizing a gesture. While a gesture is being recognized, since there is some distance of a hand from the display panel, the photosensitive sensing circuit 1 cannot detect any difference between the valleys and the ridges, and the photosensitive diode 11 can only calculate longitudinal coordinates, i.e., z coordinates, of respective components of the gesture by generating output signals corresponding to reflected light from a hand, and detecting the differences between transmission and reception instances of time of the reflected light at different positions. Thereafter three-dimension coordinates of the gesture can be determined in combined with x and y coordinates calculated from a photo taken by a front camera, to thereby recognize the gesture. Of course, the x and y coordinates can be calculated from the differences between the signals output by the photosensitive sensing circuits 1 at the different positions instead of the front camera, although the embodiment of this disclosure will not be limited thereto.

Optionally in the display panel above according to the embodiment of this disclosure, the projection of the infrared light-emitting source 2 in the direction perpendicular to the display panel does not overlap with the projection of the photosensitive sensing circuit 1 in the direction, so that infrared light emitted by the infrared light-emitting source 2 will not be received directly by the photosensitive sensing circuit 1 so as not to affect a result of fingerprint recognition.

Optionally in the display panel above according to the embodiment of this disclosure, as illustrated in FIG. 4, the display panel is generally divided into a display area A, and a bezel area B surrounding the display area A, and the photosensitive sensing circuits 1 can be located in the display area.

The display area A can further include: a plurality of pixel elements 3 arranged in an array. At least a part of the pixel elements 3 include at least four sub-pixel areas 31, where one of the infrared light-emitting sources 2 is arranged in one of the sub-pixel areas 31, and sub-pixel structures R, B, and G for displaying are arranged in the remaining sub-pixel areas 31.

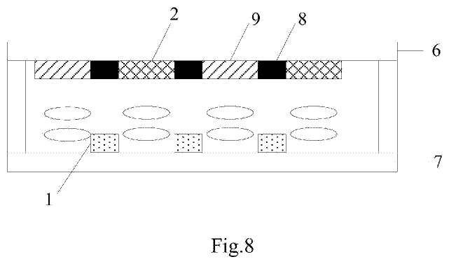

Optionally the infrared light-emitting sources 2 are arranged in the sub-pixel areas 31, so that the infrared light-emitting sources 2 can be fabricated at the same time as some layers of the sub-pixel structures R, B, and G to thereby simplify a massive production process. As illustrated in FIG. 5 and FIG. 6, for example, when the sub-pixel structures R, B, and G are Organic Light-Emitting Diodes (OLEDs) located on an underlying substrate 4, the infrared light-emitting sources 2 include an infrared electroluminescent layer, which can be a common cathode layer of the organic light-emitting diodes, or the like.

Optionally in the display panel above according to the embodiment of this disclosure, as illustrated in FIG. 4, the projection of the photosensitive sensing circuit 1 in the direction perpendicular to the display panel lies at a gap between the sub-pixel areas 31.

Optionally the photosensitive sensing circuit 1 is arranged at the gap between the sub-pixel areas 31, so that the projection, of the infrared light-emitting source 2 arranged in the sub-pixel area 31, in the direction perpendicular to the display panel does not overlap with the projection of the photosensitive sensing circuit 1 in that direction; and the photosensitive sensing circuits 1 will not hinder the sub-pixel structures R, B, and G for displaying, from operating normally.

Optionally in the display panel above according to the embodiment of this disclosure, as illustrated in FIG. 5, the sub-pixel structures R, B, and G can be Organic Light-Emitting Diodes (OLEDs) located on an underlying substrate 4, and there is typically a protective cover 5 arranged on a side of the organic light-emitting diodes away from the underlying substrate 4.

The photosensitive sensing circuit 1 can be located on a surface of the protective cover 5 facing the organic light-emitting diodes.

Optionally the photosensitive sensing circuit 1 is formed on the protective cover 5, so that there is a long distance between the photosensitive sensing circuit 1 and the Organic Light-Emitting Diodes (OLEDs), thus lowering signal interference between them.

Optionally in the display panel above according to the embodiment of this disclosure, as illustrated in FIG. 6, the sub-pixel structures R, B, and G can be organic light-emitting diodes located on the underlying substrate 4, and there are typically pixel definition layers 32 arranged between the respective sub-pixel areas 31.

The photosensitive sensing circuit 1 can be located between the pixel definition layer 32 and the underlying substrate 4.

Optionally a driver circuit for the organic light-emitting diodes is further arranged between the pixel definition layer 32 and the underlying substrate 4, so the photosensitive sensing circuit 1 can be fabricated at the same time as the driver circuit to thereby simplify a massive production process.

Optionally in the display panel above according to the embodiment of this disclosure, as illustrated in FIG. 7, the display panel can further be a liquid crystal display panel, and optionally include an opposite substrate 6 and an array substrate 7 arranged opposite to each other; and there is typically a black matrix 8 arranged on a side of the opposite substrate 6 facing the array substrate 7.

The photosensitive sensing circuit 1 can be located on the surface of the black matrix 8 away from the opposite substrate 6.

Optionally the photosensitive sensing circuit 1 will not be seen from the display face of the display panel due to the shielding of black matrix 8, so an image will not be hindered from being displayed. Furthermore there is a long distance between the photosensitive sensing circuit 1 arranged on the opposite substrate 6 and display signal lines in the array substrate 7, thus lowering signal interference between them.

Optionally in the display panel above according to the embodiment of this disclosure, as illustrated in FIG. 8, the display panel can be a liquid crystal display panel, and optionally include an opposite substrate 6 and an array substrate 7 which are arranged opposite to each other.

The photosensitive sensing circuit 1 can alternatively be located on a side of the array substrate 7 facing the opposite substrate 6.

Optionally there is typically a display driver circuit arranged on the array substrate 7, so the photosensitive sensing circuit 1 can be fabricated at the same time as the display driver circuit to thereby simplify a massive production process.

Optionally in the display panel above according to the embodiment of this disclosure, as illustrated in FIG. 7 and FIG. 8, typically color filter sheets 9 are further arranged on a side of the opposite array substrate 6 facing the array substrate 7.

The infrared light-emitting sources include infrared electroluminescent layers located at the same layer as the color filter sheets 9.

Optionally in the display panel above according to the embodiment of this disclosure, the display panel includes a display area A, and a bezel area B surrounding the display area A; and the infrared light-emitting source 2 can alternatively be located in the bezel area B, so that the display resolution in the display area A will not be affected.

Based upon the same inventive idea, an embodiment of this disclosure further provides a display device including the display panel above according to embodiments of this disclosure. The display device can be a mobile phone, a tablet computer, a TV set, a display, a notebook computer, a digital photo frame, a navigator, or any other product or component with a display function. All the other components indispensable to the display device shall readily occur to those ordinarily skilled in the art, and a repeated description thereof will be omitted, although embodiments of this disclosure will not be limited thereto. Reference can be made to embodiments of the display panel above for an implementation of the display device, and a repeated description thereof will be omitted.

Optionally in the display device above according to the embodiment of this disclosure, the display device can further include a front camera configured to take a photo, so that the x and y coordinates of the gesture can been calculated precisely, and the three-dimension coordinates of the gesture can be determined in combination with the z coordinate obtained by the photosensitive sensing circuit 1 to thereby recognize the gesture.

Based upon the same inventive idea, an embodiment of this disclosure further provides a method for driving the display device above, where the method includes the following steps.

Bias voltage is applied to at least the respective driver signal lines in a target detection area, where the bias voltage is higher than avalanche voltage of the photosensitive diodes.

At least the respective scan signal lines in the target detection area are scanned sequentially in rows, and at least output signals of the respective read signal lines in the target detection area are obtained.

Optionally in the driving method above according to the embodiment of this disclosure, the switch transistors connected with the scan signal lines are controlled by the scan signal lines to be switched on or off, and when the switch transistors are switched on, the bias voltage higher than the avalanche voltage is applied to the photosensitive diodes over the drive signal lines. While a fingerprint is being recognized, the photosensitive diodes are broken through reversely due to infrared light reflected by ridges, so that large current is produced, and output to the read signal lines through the sample resistors; and the photosensitive diodes corresponding valleys output zero current. In this way, the valleys and the ridges are distinguished from each other. The photosensitive diodes being illuminated are broken through reversely so that the large current is produced, so there is a significant difference in detection signal between the valleys and the ridges while a fingerprint is being recognized in the driving method according to the embodiment of this disclosure, thus lowering the difficulty of detection in an IC detection circuit, and improving the precision of detection in fingerprint recognition.

Optionally in the driving method above according to the embodiment of this disclosure, the driving method above can be performed only in the target detection area to thereby save power consumption for driving.

Optionally in the driving method above according to the embodiment of this disclosure, bias voltage can be applied to all the driver signal lines concurrently; and the respective scan signal lines can be scanned sequentially in rows, and output signals of the respective read signal lines can be obtained. In this way, an instantaneous workload of calculation can be reduced, and also the number of wires routed throughout the panel, and a burden on the IC can be lowered.

Optionally in the driving method above according to the embodiment of this disclosure, while a floating touch, i.e., a gesture, is being detected, the method can further include: taking a photo of a gesture using the front camera, and determines positional coordinates of the gesture in a plane. The front camera can take a photo, so that the x and y coordinates of the gesture can be calculated precisely, and the three-dimension coordinates of the gesture can be determined in combination with the z coordinate obtained by the photosensitive sensing circuits 1 to thereby recognize the gesture.

Optionally in the driving method above according to the embodiment of this disclosure, the method can further include: detecting a target detection area according to the determined positional coordinates of the gesture in the plane, that is, while a floating touch, i.e., a gesture, is being detected, firstly the front camera determines the positional coordinates of the gesture in the plane, and after the target detection area is determined, the driving method above can be performed only in the target detection area.

In the display panel, the display device, and the method for driving the same according to the embodiments of this disclosure, the switch transistors connected with the scan signal lines are controlled by the scan signal lines to be switched on or off, and when the switch transistors are switched on, the bias voltage higher than the avalanche voltage is applied to the photosensitive diodes over the drive signal lines. While a fingerprint is being recognized, the photosensitive diodes are broken through reversely due to infrared light reflected by ridges, so that large current is produced, and output to the read signal lines through the sample resistors; and the photosensitive diodes corresponding valleys output zero current. In this way, the valleys and the ridges are distinguished from each other. The photosensitive diodes being illuminated are broken through reversely so that the large current is produced, so there is a significant difference in detection signal between the valleys and the ridges while a fingerprint is being recognized in the embodiments of this disclosure, thus lowering the difficulty of detection in an IC detection circuit, and improving the precision of detection in fingerprint recognition.

Evidently those skilled in the art can make various modifications and variations to the disclosure without departing from the spirit and scope of the disclosure. Thus the disclosure is also intended to encompass these modifications and variations thereto so long as the modifications and variations come into the scope of the claims appended to the disclosure and their equivalents.

1. A display panel, comprising: a plurality of photosensitive sensing circuits arranged in an array, a plurality of scan signal lines corresponding to each row of the plurality of photosensitive sensing circuits, and a plurality of read signal lines, and a plurality of drive signal lines, both of which correspond to each column of the plurality of photosensitive sensing circuits, the display panel is divided into a display area, and a bezel area surrounding the display area, and the display area comprises: a plurality of pixel elements arranged in an array; projections of the photosensitive sensing circuits in a direction perpendicular to the display panel lie at gaps between the sub-pixel areas, and each of the photosensitive sensing circuits comprises a photosensitive diode, a switch transistor and a sample resistor, wherein:
the switch transistor comprises a gate connected with a corresponding scan signal line, a source connected with a cathode of the photosensitive diode, and a drain connected with a corresponding drive signal line;
the photosensitive diode comprises an anode connected with a first end of the sample resistor, and a second end of the sample resistor is grounded; and
the first end of the sample resistor is connected with a corresponding read signal line.

2. The display panel according to claim 1, further comprises at least one infrared light-emitting source, and the photosensitive diode is an infrared photosensitive diode; and
a projection of the infrared light-emitting source in a direction perpendicular to the display panel does not overlap with projections of the photosensitive sensing circuits in the direction.

3. The display panel according to claim 2, wherein
at least a part of the plurality of pixel elements comprise at least four sub-pixel areas, where one infrared light-emitting source is arranged in one of the sub-pixel areas, and sub-pixel structures for displaying are arranged in a rest of the sub-pixel areas.

4. (canceled)

5. The display panel according to claim 1, wherein the sub-pixel structures are organic light-emitting diodes located on an underlying substrate of the display panel, and a protective cover is arranged on a side of the organic light-emitting diodes away from the underlying substrate; and
the photosensitive sensing circuits are located on the surface of the protective cover facing the organic light-emitting diodes.

6. The display panel according to claim 1, wherein the sub-pixel structures are organic light-emitting diodes located on an underlying substrate of the display panel, and pixel definition layers are arranged between each of the sub-pixel areas; and
the photosensitive sensing circuits are located between the pixel definition layers and the underlying substrate.

7. The display panel according to claim 1, wherein the display panel is a liquid crystal display panel, and comprises an opposite substrate and an array substrate; the opposite substrate and an array substrate are arranged opposite to each other; and a black matrix is arranged on a side of the opposite substrate facing the array substrate; and
the photosensitive sensing circuits are located on a surface of the black matrix away from the opposite substrate.

8. The display panel according to claim 1, wherein the display panel is a liquid crystal display panel, and comprises an opposite substrate and an array substrate, the opposite substrate and an array substrate are arranged opposite to each other; and
the photosensitive sensing circuits are arranged on a side of the array substrate facing the opposite substrate.

9. The display panel according to claim 7, wherein color filter sheets are arranged on a side of the opposite array substrate facing the array substrate; and
the infrared light-emitting source comprises an infrared electroluminescent layer; the infrared electroluminescent layer and the color filter sheets are located at a same layer.

10. The display panel according to claim 2, wherein the infrared light-emitting source is located in the bezel area.

11. A display device, comprises the display panel according to claim 1.

12. The display device according to claim 11, further comprises a front camera.

13. A method for driving the display device according to claim 11, the method comprises:
applying bias voltage to each of driver signal lines at least in a target detection area, wherein the bias voltage is higher than an avalanche voltage of the photosensitive diodes; and
scanning each of scan signal lines at least in the target detection area sequentially in rows, and obtaining at least output signals of each of read signal lines in the target detection area.

14. The driving method according to claim 13, wherein applying bias voltage to each of driver signal lines at least in a target detection area comprises:
applying the bias voltage to all of the driver signal lines; and
scanning each of scan signal lines at least in the target detection area sequentially in rows, and obtaining at least output signals of each of read signal lines in the target detection area comprises:
scanning each of the scan signal lines sequentially in rows, and obtaining the output signals of each of the read signal lines.

15. The driving method according to claim 13, wherein while a floating touch is being detected, the method further comprises:
taking a photo of a gesture using a front camera, determining positional coordinates of a gesture in a plane, and generating output signals corresponding to reflected light from a hand, and detecting differences between transmission and reception instances of time of the reflected light at different positions to calculate a longitudinal coordinate of the gesture.

16. The driving method according to claim 15, further comprises:
determining the target detection area according to determined positional coordinates of the gesture in the plane and the longitudinal coordinate.
